(19) United States
(12) Patent Application Publication
(10) Pub. No.: US 2008/0217651 A1
(43) Pub. Date: Sep. 11, 2008

(54) Photodetector

(75) Inventors: Chee-Wee Liu, Taipei (TW); Chu-Hsuan Lin, Taipei (TW); Cheng-The Yu, Taipei (TW)

Correspondence Address: SUTHERLAND ASBILL & BRENNAN LLP, 999 PEACHTREE STREET, N.E., ATLANTA, GA, 30309, US

(73) Assignee: NATIONAL TAIWAN UNIVERSITY, Taipei (TW)

(21) Appl. No.: 11/829,257

(22) Filed: Jul. 27, 2007

(30) Foreign Application Priority Data
Mar. 5, 2007 (TW) 96107588

(51) Int. Cl. H01L 31/028; H01L 31/0224

(52) U.S. Cl. 257/184; 438/98; 257/E31.124; 257/E31.011

(57) ABSTRACT

A photodetector is provided. The photodetector includes a base piece; a germanium layer mounted on the base piece and including a first area and a second area; a first metal electrode mounted on the first area; an insulation layer mounted on the second area; and a second metal electrode mounted on the insulation layer.

### FIELD OF THE INVENTION

The present invention relates to a structure and the manufacturing method of a semiconductor photodetector, and more particularly to a structure and the manufacturing method of a semiconductor photodetector where a metal-insulation layer-semiconductor is formed on the base piece having a germanium layer formed thereon.

### BACKGROUND OF THE INVENTION

In the semiconductor photodetector, the photo energy is received by the sensor and transferred to an electric signal for the photo-communication and photo detecting.

In the Taiwan Patent No. 125431, the metal-oxide semiconductor tunneling diode (MOS tunneling diode) is used as the photo detector. However, the detectable wavelength thereof is limited by the energy gap of the semiconductor material, because the photon energy needs to be larger than the energy gap of the material in order to generate the extra electron-hole pairs. If the silicon (Si) is used as the substrate, the cut-off wavelength is about 1.1 μm, and if the germanium (Ge) is used as the substrate, the cut-off wavelength is about 1.85 μm. Therefore, if the photo detection is required to be applied to the wavelengths of 1.3 μm and 1.55 μm, the germanium has to be used as the substrate. However, the substrate completely made of germanium is very expensive, so the cost down thereof is the major problem to be solved.

Moreover, in the U.S. Pat. No. 5,374,564, the Smart-cut process is provided, which implants the hydrogen ion into the inner layer of the wafer by using the ion implantation technique, and controls the implantation depth through the implantation energy. The wafer can be cut through the property of the implanted hydrogen ion which will enable the wafer separation in high temperature. Using such technique can slice the expensive germanium substrate into pieces of thin germanium chips.

Furthermore, in the U.S. Pat. No. 6,833,195B1, the Intel Corporation implants the ion into the germanium substrate at first. Then the germanium substrate and the silicon substrate are ostensibly activated and bonded together. Finally, the germanium substrate and the silicon substrate are heated, as mentioned in the method of the Smart-cut process, for cutting the germanium substrate, so as to obtain a silicon substrate with a thin germanium layer.

In order to overcome the problem of the expensive germanium material, a photodetector and the manufacturing method thereof are provided. The particular design in the present invention not only solves the problems described above, but also is easy to be implemented. Thus, the invention has the utility for the industry.

### SUMMARY OF THE INVENTION

In accordance with the present invention, a photodetector and the manufacturing method thereof for forming the metal-insulation-semiconductor on the base piece with a germanium layer are provided, so as to solve the present problem of the expensive germanium material.

According to one aspect of the present invention, a photodetector is provided. The photodetector includes a base piece; a germanium layer mounted on the base piece and including a first area and a second area; a first metal electrode mounted on the first area; an insulation layer mounted on the second area; and a second metal electrode mounted on the insulation layer.

Preferably, the photodetector further comprises a voltage source comprising a first electrode terminal connected to the first metal electrode; and a second electrode terminal connected to the second metal electrode, wherein, the voltage source provides a bias voltage for generating a tunneling current, so that the photodetector produces a photocurrent while it receives a light.

Preferably, the base piece comprises a silicon substrate; and an insulation film mounted on the silicon substrate, wherein the germanium layer is bonded on the insulation film.

Preferably, the insulation film is a silica film.

Preferably, the base piece is a plastic board.

Preferably, the base piece is a glass board.

Preferably, the germanium film is a doped germanium film.

Preferably, the first metal electrode is an aluminum electrode.

Preferably, the insulation layer is made of a silicon dioxide.

Preferably, the second metal electrode is a platinum electrode.

According to another aspect of the present invention, a method for manufacturing a photodetector is provided. The method includes the steps of a) providing a supporting substrate with a germanium layer mounted thereon, wherein the germanium layer has a first area and a second area; b) forming an insulation layer on the first and the second areas; c) forming a second metal electrode on the insulation layer; d) removing apportion of the insulation layer on the first area; and e) forming a first metal electrode on the first area.

Preferably, the step b) is performed by a low temperature liquid depositing technique.

The present invention has the advantage of avoiding using the seldom and expensive germanium material, which are replaced by the cheaper silicon dioxide-silicon substrate, the glass substrate or other substrates with the function of carrying and transferring the germanium film.

Moreover, the conventional metal-insulator-semiconductor photodetector uses the silicon as the semiconductor, so the method for manufacturing the insulation layer on the semiconductor uses the high temperature heat growing process to generate a thermal oxide as the insulation layer. However, when the germanium is used as the semiconductor, the high temperature heat growing process cannot be used because of the low melting point of the germanium. Even if the high temperature heat growing process is used, the germanium dioxide insulation layer formed is unstable. The present invention preferably provides a silicon dioxide insulation layer by using the low temperature liquid depositing technique.

Furthermore, the platinum is used in the present invention instead of the aluminum gate of the conventional metal-insulator-semiconductor photodetector. Therefore, the present invention can stop the electron tunneling from the metal to the semiconductor under the reverse bias, thereby greatly decreasing the dark current.

### BRIEF DESCRIPTION OF THE DRAWINGS

FIGS. 1(a)-1(f) are schematic diagrams showing the sectional view of the photodetector according to a preferred embodiment of the present invention;

FIG. 2 is a transmission electron microscope (TEM) photograph of the germanium-on-insulator metal-insulator-semiconductor structure;

FIG. 3 is a current-voltage diagram of the germanium-on-insulator metal-insulator-semiconductor device;

FIG. 4 is a diagram showing the structure of germanium-on-glass metal-insulator-semiconductor device and the TEM photograph of germanium-on-glass structure; and

FIG. 5 is a current-voltage diagram of the germanium-on-glass metal-insulator-semiconductor device.

### DETAILED DESCRIPTION OF THE PREFERRED EMBODIMENT

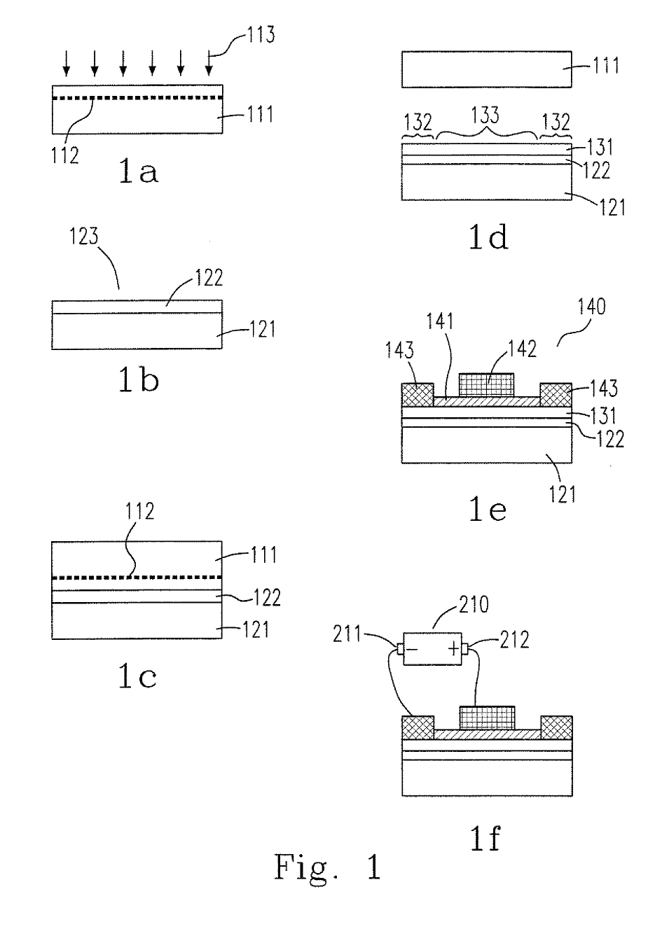

Please refer to FIGS. 1(a)-1(f), which show the sectional view of the photodetector according to a preferred embodiment of the present invention.

Please refer to FIG. (1a), the first step of the present invention uses the Smart-cut process provided by the U.S. Pat. No. 5,374,564, which implants the hydrogen ion 113 into the position of the interface 112 of the N-type germanium substrate 111 by using the ion implantation technique under the following process conditions: the energy 200 KeV, the implantation quantity=1E17 (cm⁻²), wherein the implantation depth is associated with the implantation energy, and the implantation concentration is associated with the temperature and the time for the wafer separating process.

Please refer to FIG. (1b), which shows the step of growing a silicon dioxide of 80 nm 122 on a P-type silicon wafer 121, wherein the base piece 123 is composed of the silicon wafer 121 and the silicon dioxide 122.

Next, please refer to the technique mentioned in the U.S. Pat. No. 6,833,195B1, wherein the Intel Corporation implants the ion into the geranium substrate at first. Then the germanium substrate and the silicon substrate are ostensibly activated and bonded together. Finally, the germanium substrate and the silicon substrate are heated, as mentioned in the method of the Smart-cut process, for cutting the germanium substrate, so as to obtain a silicon substrate with a thin germanium layer. The technique of the U.S. Pat. No. 6,833,195B1 will be applied to the later steps of this preferred embodiment.

Next, the germanium substrate 111 and the silicon wafer 121 are washed by the supersonic with the deionized water for eliminating the dust particle on the silicon wafer surface. The silicon wafer 121 is immersed in the SC-1 solution (NH₄OH:H₂O₂:H₂O˜0.5:1:5) at 80° C. for 15 minutes, and the germanium substrate 111 is immersed in the potassium hydroxide-deionized water solution (KOH:H₂O˜1:5) at 80° C. for 15 minutes. Afterward, the germanium substrate 111 and the silicon wafer 121 are respectively washed with the deionized water for 5 minutes, and dried by the high pressure pure Nitrogen. At this time, the surfaces of the germanium substrate 111 and the silicon wafer 121 are fully spread with the hydrophilic OH⁻ bonds.

Please refer to FIG. (1c), after the bonding surface of the germanium substrate 111 and the silicon wafer 121 is aligned, the germanium substrate 111 and the silicon wafer 121 are bound directly at the room temperature in the vacuum chamber.

Please refer to FIG. (1d), the bound germanium substrate 111 and silicon wafer 121 is heated to 150° C. at 1 atmospheric pressure in the Nitrogen purge environment and maintained for 12 hours for enhancing the bonding strength and separating the wafer by the hydrogen ion implanted into the interface 112 thereof. After separating, the base piece 123 has a successfully transferred thin germanium layer 131 thereon, which is divided into a first area 132 and a second area 133.

After separating, the surface of the successfully transferred thin germanium layer 131 is evened by the evening techniques, such as the chemical mechanical polishing, for decreasing the influence of the rough surface on the element properties.

Please refer to FIG. (1e). The silicon dioxide insulation layer 141 is formed by the low temperature liquid depositing technique as a tunneling gate insulation layer Finally, a Platinum (Pt) layer is sputtered on the insulation layer 141. The second metal electrode 142 is formed on the second area 133 by using the lithography and the etching techniques to remove the extra Platinum. The insulation layer 141 on the first area 132 is removed by using the lithography and the etching techniques, and the etched space is plated with Aluminum to form the first metal electrode 143 for ohmic contact, thereby completing the photodetector of this preferred embodiment.

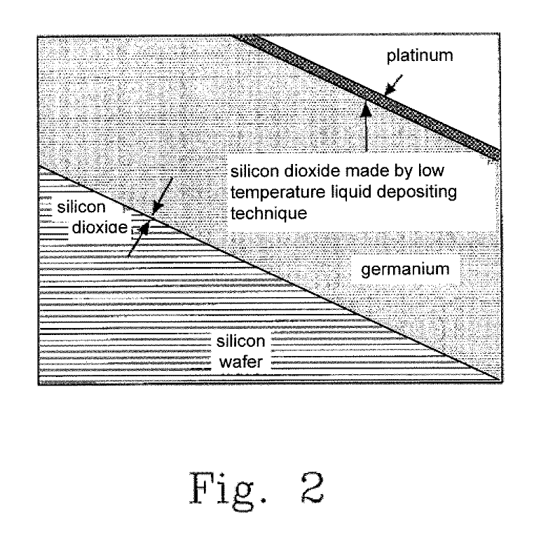

Please refer to FIG. 2, which shows the transmission electron microscope (TEM) photograph of the metal-insulator-semiconductor diode demonstrated on germanium-on-insulator substrate, i.e. the TEM photograph of the photodetector according to the preferred embodiment of the present invention which is manufactured based on the above-mentioned processes. In this photography, the respective structures of the second metal electrode 142 formed by platinum, the silicon dioxide insulation layer 141 formed by the low temperature liquid depositing technique, the germanium layer (Ge) 131, the silicon dioxide (SiO₂) 122 and the silicon (Si) wafer 121 are shown clearly.

Please refer to FIG. (1f), which shows the last step of providing a voltage source 210. The voltage source 210 includes a first electrode 211 and a second electrode 212. The first electrode 211 is connected to the first metal electrode 143 and the second electrode 212 is connected to the second metal electrode 142. The voltage source 210 provides a bias to generate a tunneling current, which enables the photodetector 140 to generate a light current when lighted.

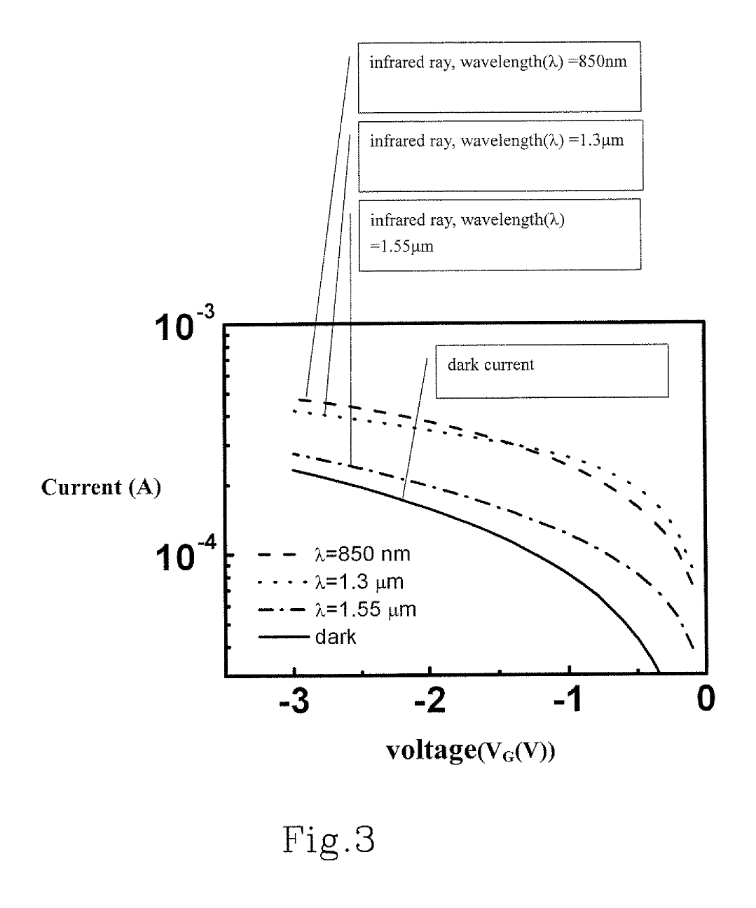

Please refer to FIG. 3, which is a current-voltage diagram of the germanium-on-insulator metal-insulator-semiconductor device, i.e. the current-voltage diagram of the photodetector according to a preferred embodiment of the present invention which is manufactured based on the above-mentioned processes. In the diagram, the cross axle represents the voltage and the vertical axle represents the current, in which the first three lines from the top to bottom represent the voltage-current relationships when the photodetector 140 is lighted by the infrared rays of 850 nm, 1.3 μm and 1.55 μm respectively. The fourth line in the diagram represents the voltage-current relationship of the dark current without being lighted by the infrared ray.

In the preferred embodiment of the present invention, the base piece 123 only includes the silicon wafer 121 and the silicon dioxide 122. However, in other embodiments, the base piece 123 can be a plastic substrate, a glass substrate or other substrates with the function of carrying and transferring the germanium film.

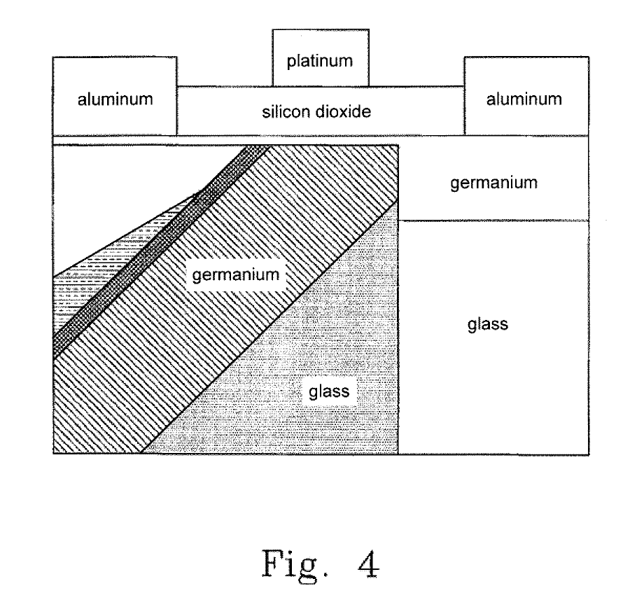

Please refer to FIG. 4, which shows a diagram of the germanium-on-glass metal-insulator-semiconductor device and the TEM photograph of the germanium-on-glass structure with in the present invention, in which the base piece 123 formed by the silicon wafer 121 and the silicon dioxide 122 is replaced by the glass substrate. In this diagram, the structures of the second metal electrode 142 made of platinum, the silicon dioxide insulation layer 141 formed by the low temperature liquid depositing technique, the germanium (Ge) layer 131 and the glass substrate are shown clearly in sequence.

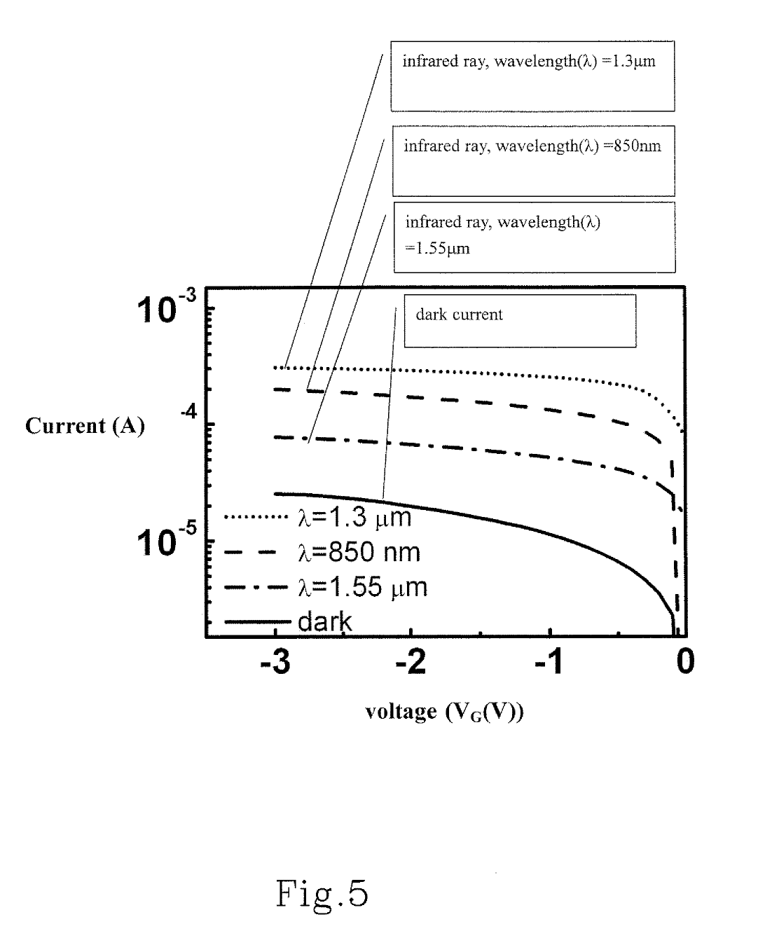

Please refer to FIG. 5, which is a current-voltage diagram of the germanium-on-glass metal-insulator-semiconductor device in the present invention, where the base piece 123 formed by the silicon wafer 121 and the silicon dioxide 122 in the preferred embodiment of the present invention is replaced by the glass substrate. In the diagram, the cross axle represents the voltage and the vertical axle represents the current, in which the first three lines from the top to bottom represent the voltage-current relationships when the photodetector 140 is lighted by the infrared rays of 1.3 μM, 850 nm and 1.55 μm respectively. The fourth line in the diagram represents the voltage-current relationship of the dark current without being lighted by the infrared ray.

The insulation layer 141 is the silicon dioxide formed by the low temperature liquid depositing technique in the preferred embodiment. However, in other embodiments, the insulation layer 141 can be the silicon dioxide formed by other techniques or other insulation substances.

The germanium layer 131 is separated from the N-type germanium substrate 111 in the preferred embodiment. However, in other embodiments, the germanium layer 131 can also be separated from a P-type or a non-doping germanium substrate 111, in which the doping concentration thereof can be adjusted arbitrarily according to actual needs. Moreover, the germanium substrate 111 can be a single-crystal, a poly-crystal or an amorphous substrate, and can also be a {100}, a {110} or a {111} substrate.

The first metal electrode 143 is made of aluminum in the preferred embodiment. However, in other embodiments, the first metal electrode 143 can also be made of other metals.

The second metal electrode 142 is made of platinum in the preferred embodiment. However, in other embodiments, the second metal electrode 142 can also be made of other metals.

The bonded germanium substrate 111 and silicon wafer 121 are heated to 150° C. at 1 atmospheric pressure in the Nitrogen purge environment and maintained for 12 hours for enhancing the bonding strength and separating the wafer by the hydrogen ion implanted into the interface 112 thereof in the preferred embodiment. However, in other embodiments, the temperature can be between 150° C. and 600° C., and the heating time can be minutes to hours for achieving the purpose of separating.

While the invention has been described in terms of what is presently considered to be the most practical and preferred embodiment, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A photodetector, comprising:
a base piece
a germanium layer mounted on the base piece and comprising a first area and a second area;
a first metal electrode mounted on the first area;
an insulation layer mounted on the second area; and
a second metal electrode mounted on the insulation layer.

2. The photodetector of claim 1 further comprising a voltage source, the voltage source comprising:
a first electrode terminal connected to the first metal electrode; and
a second electrode terminal connected to the second metal electrode,
wherein, the voltage source provides a bias voltage for generating a tunneling current, so that the photodetector produces a photocurrent while it receives a light.

3. The photodetector of claim 1, wherein the base piece is a substrate operable to support and bond with the germanium layer.

4. The photodetector of claim 3, wherein the base piece comprises:
a silicon substrate; and
an insulation film mounted on the silicon substrate,
wherein the germanium layer is bonded on the insulation film.

5. The photodetector of claim 4, wherein the insulation film comprises a silicon dioxide film.

6. The photodetector of claim 3, wherein the base piece comprises a plastic board.

7. The photodetector of claim 3, wherein the base piece comprises a glass board.

8. The photodetector of claim 1, wherein the germanium film comprises a doped germanium film.

9. The photodetector of claim 1, wherein the first metal electrode comprises an aluminum electrode.

10. The photodetector of claim 1, wherein the insulation layer comprises a silicon dioxide insulation layer.

11. The photodetector of claim 1, wherein the second metal electrode comprises a platinum electrode.

12. A method for manufacturing a photodetector, comprising:
providing a supporting substrate with a germanium layer mounted thereon, wherein the germanium layer has a first area and a second area;
forming an insulation layer on the first area and the second area;
forming a second metal electrode on the insulation layer;
removing apportion removing a portion of the insulation layer on the first area; and
forming a first metal electrode on the first area.

13. The method of claim 12, wherein forming an insulation layer comprises forming an insulation layer by a low temperature liquid depositing technique.
